(19) United States
(12) Patent Application Publication
(10) Pub. No.: US 2023/0361252 A1
(43) Pub. Date: Nov. 9, 2023

(54) LED DEVICE

(71) Applicant: PORO TECHNOLOGIES LTD, Cambridge, Cambridgeshire (GB)

(72) Inventors: Tongtong ZHU, Cambridge (GB); Yingjun LIU, Cambridge (GB); Muhammad ALI, Cambridge (GB)

(21) Appl. No.: 18/044,811

(22) PCT Filed: Sep. 10, 2021
(86) PCT No.: PCT/GB2021/052366

§ 371 Date: Mar. 10, 2023

(30) Foreign Application Priority Data
Sep. 11, 2020 (GB) 2014318.6

(51) Int. Cl. H01L 33/46; H01L 33/50; H01L 33/06; H01L 33/10; H01L 25/075

(52) U.S. Cl. CPC H01L 33/46; H01L 33/502; H01L 33/06; H01L 33/10; H01L 25/0753

(57) ABSTRACT

An LED device comprises a plurality of light-emitting diodes (LEDs), and an optical filter arranged to filter light emitted by the plurality of LEDs. The optical filter comprises a first region arranged to filter light emitted from a first portion of the plurality of LEDs, in which the first region of the optical filter comprises a Distributed Bragg Reflector (DBR) configured to prevent transmission of light of a predetermined wavelength λ₁. The LED device may comprise a colour-conversion material positioned between the first portion of the LEDs and the DBR, the colour-conversion material being configured to emit light at one or more wavelengths different from the emission wavelength λ₁ of the first portion of LEDs. An optical filter and a method of manufacture are also provided.

The invention relates to an LED device and an optical filter for an LED Device comprising a plurality of light-emitting-diodes (LEDs). In particular, the invention relates to an optical filter usable to convert a plurality of single-colour LEDs into a multi-coloured LED display.

### BACKGROUND

Inorganic LED-based micro-displays are currently manufactured based on two designs. In three-colour LED micro-displays, InGaN (blue and green) and AlGaInP (red) micro-LEDs are integrated and bonded onto the micro-display. However, precise control of this process on the required scale is extremely challenging. An alternative approach uses a single colour of LED, such as InGaN blue LEDs, paired with phosphors to create white-color backlight, which can then be colour-filtered to produce an image. A drawback of this approach is the low absorption coefficient of the phosphor, as this means that a thick phosphor layer is needed, and also causes pixel-pixel cross-talk.

US patent application US20200152841A1 suggests an alternative approach of providing an array of blue LEDs, and altering the colours of selected diodes by electrochemically etching the n-GaN layer of those diodes and impregnating the etched layers with colour-conversion quantum dots. By impregnating selected diodes with a red quantum dot composition, impregnating other diodes with a green quantum dot composition, and leaving some blue LEDs without any colour-converting quantum dots, the same LED device can be provided with red, green and blue pixels.

The approach of US20200152841A1 has the following drawbacks:
that the colour-conversion-efficiency of colour-conversion quantum dots is not perfect, so residual blue light may be emitted by pixels that are intended to be red or green;
adjacent pixels can suffer from cross-talk between different colours;
quantum dots impregnated into the LED structure can suffer from problems with stability and reliability; and
LED wafers must be further processed by electrochemical porosification and impregnation of quantum dots directly into the LED structures, which may be inefficient and particularly challenging on wafers containing a high density of LEDs.

### SUMMARY OF THE INVENTION

The present application relates to an LED device, and an optical filter for an LED device.

The invention is defined in the independent claims, to which reference should now be made. Preferred or advantageous features of the invention are defined in the appended sub-claims.

According to a first aspect of the invention there is provided an LED device, comprising:
a plurality of light-emitting diodes (LEDs), and
an optical filter arranged to filter light emitted by the plurality of LEDs,
in which the optical filter comprises a first region arranged to filter light emitted from a first portion of the plurality of LEDs, in which the first region of the optical filter comprises a Distributed Bragg Reflector (DBR) configured to prevent transmission of light of a predetermined wavelength λ₁ out of the LED device.

The optical filter preferably comprises a second region arranged to filter light emitted from a second portion of the plurality of LEDs. The second region of the optical filter preferably allows transmission of light of wavelength λ₁. The second region may, however, be configured to reduce the brightness of light of wavelength λ₁ transmitted from the second portion of the plurality of LEDs, so that the light emitted out of the device from the second region is not significantly brighter than the light emitted from the first region.

The plurality of LEDs are preferably monochromatic LEDs, particularly preferably monochromatic blue LEDs or UV LEDs. Preferably all of the LEDs in the plurality of LEDs emit at the same wavelength.

In an alternative embodiment, the plurality of LEDs may comprise a portion of LEDs that emit light at a first wavelength, and a portion of LEDs that emit light at a second wavelength different from the first wavelength.

The plurality of LEDs may comprise monochromatic LEDs or panchromatic LEDs.

In preferred embodiments of the invention, λ₁ is the emission wavelength of the plurality of LEDs. At least some of the plurality of LEDs preferably emit light at wavelength λ₁. In a particularly preferred embodiment, all of the plurality of LEDs preferably emit light at wavelength λ₁.

The second portion of the optical filter is preferably configured to allow transmission of light with wavelength λ₁ emitted by the second portion of the plurality of LEDs, while the first portion of the optical filter is configured to prevent transmission of light of wavelength λ₁ emitted by the first portion of the plurality of LEDs.

The idea of blocking transmission of the emission wavelength λ₁ of some of the plurality of LEDs in the device may seem counterintuitive. However, the present inventors have found that providing an optical filter to prevent transmission of λ₁ wavelength light is particularly suitable for LED devices in which the emission wavelength of the LED is somehow converted to a different wavelength λ₂ before emission from the device. In LED devices containing colour-conversion quantum dots (QDs), for example, the use of the DBR to prevent λ₁ transmission from the second portion of the plurality of LEDs can prevent blue light leakage out of areas of the device that are supposed to emit other colours. The use of the optical filter therefore advantageously solves many of the cross-talk and blue-light leakage problems that may be suffered by the devices of US20200152841A1.

Preferably the second portion of the plurality of LEDs are monochromatic blue LEDs, and the second region of the optical filter is configured to transmit blue light emitted by the blue LEDs.

The DBR is preferably configured to prevent transmission of blue light, to solve the problem of blue light leaking from pixels that are supposed to convert the emission wavelength to a different wavelength λ₂.

The first region of the optical filter is preferably configured to allow transmission of green and/or red light. The LED device may therefore provide RGB pixels.

The first portion of the plurality of LEDs comprises preferably LEDs configured to emit green light, and/or LEDs configured to emit red light.

The first portion of the plurality of LEDs preferably comprises monochromatic LEDs (preferably blue or UV LEDs) which emit at wavelength λ₁, and the device may comprise colour conversion material arranged to convert the emitted light from the first portion of the plurality of LEDs to a converted wavelength λ₂. The colour conversion material may be colour-conversion quantum dots, phosphors, or organic or inorganic perovskites.

The colour-conversion material may advantageously absorb light of wavelength λ₁ that is emitted by the first portion of the plurality of LEDs, and emit light at a different wavelength λ₂.

The colour-conversion material may comprise a perovskite material, preferably a plurality of colour-conversion perovskite nanocrystals.

It is preferred that the plurality of LEDs comprise blue or UV LEDs which emit at wavelengths of 365-500 nm, so that the LEDs can pump the colour-converting materials to emit light at green or red wavelengths.

In a preferred embodiment, the first portion of the plurality of LEDs comprises monochromatic LEDs and the device comprises colour-conversion material positioned between the LEDs and the DBR, the colour-conversion material being configured to absorb light of wavelength λ₁ and emit light at one or more converted wavelengths λ₂ different from the emission wavelength λ₁ of the LEDs.

In a particularly preferred embodiment, the first portion of the plurality of LEDs comprises monochromatic LEDs and the device comprises a plurality of colour-conversion quantum dots positioned between the LEDs and the DBR, the colour-conversion quantum dots being configured to emit light at one or more converted wavelengths λ₂ different from the emission wavelength λ₁ of the LEDs.

Preferably, the colour-conversion material is configured to emit green light and/or red light. Particularly preferably, the colour-conversion material is configured to convert blue light into green light and/or red light.

Particularly preferably, the colour-conversion quantum dots are configured to emit green light and/or red light. Particularly preferably, the colour-conversion quantum dots are configured to convert blue light into green light and/or red light.

Preferably the second region of the optical filter does not comprise any colour-conversion material, and light emitted from the second portion of the plurality of LEDs does not undergo colour conversion.

The concept of colour-conversion quantum dots, and the process of impregnating such quantum dots into porous semiconductor material, is known in the art and as such will not be set out in detail here. For example, impregnation of colour-conversion quantum dots into the porous n-GaN layers of LEDs is disclosed in US20200152841A1. A similar approach may be used to impregnate colour-conversion quantum dots in the present invention.

The colour-conversion material is preferably impregnated within, or positioned in the emission path of, a discrete subset of the plurality of LEDs in the first portion of LEDs.

The colour-conversion quantum dots may be impregnated within, or in the emission path of, discrete subsets of the LEDs in the first portion of the plurality of LEDs. For example, the quantum dots may be impregnated into porous layers of the LED structures, such as porous n-doped layers of III-nitride material.

The colour conversion material is preferably positioned between the LED active region from which light at wavelength λ₁ is emitted, and the outlet from which light is emitted from the LED device. In other words, the colour-conversion material should preferably be positioned in the emission pathway of the LEDs, so that the colour-conversion material absorbs the light emitted by the LEDs.

In a preferred embodiment, the first region of the optical filter comprises a porous layer positioned between the LEDs and the DBR. Preferably the porous layer is coated or impregnated with colour conversion material, particularly preferably colour-conversion quantum dots.

The porous layer may have a thickness of between 1 nm and 5000 nm, preferably between 10 nm and 5000 nm, or between 50 nm and 5000 nm.

The porous layer may be formed from III-nitride semiconductor material, or alternatively another semiconductor material, or a dielectric material. As III-nitride material is particularly preferred, however, the following description relates to this embodiment.

The III-nitride material is preferably selected from the list consisting of: GaN, AlGaN, InGaN, InAlN, AlInGaN, and AlN.

The porous layer is a layer of porous material that does not form part of the DBR structure. The porous layer may form a surface layer of the optical filter, though when the optical filter is integrated into the LED device, the porous layer will be positioned between the LEDs and the DBR.

Additional layers of semiconductor material may also be formed over the porous layer, so that the porous layer is a sub-surface layer in the optical filter.

The porosity of the porous layer can be varied from 0.1-100% and pore size can be varied between 10-100 nm. Where the porous layer is porosified by electrochemical porosification, the porosity and pore size may be controlled using the doping levels or electrochemical etching conditions such as voltage, current, temperature, etc.

Where the porous layer is porosified by electrochemical porosification, the doping level in the porous layer before it is porosified can be between 1×10¹⁸-1×10²⁰ cm⁻².

In a preferred embodiment, the porous layer is a porous layer of III-nitride material, which may be electrochemically porosified using the technique described in WO2019/063957A1.

Using a porous layer of the optical filter to encapsulate and scatter as much as possible of the colour converting quantum dots/nanoparticles/nanocrystals may advantageously allow the LED device to achieve a particularly high colour conversion efficiency, to avoid cross-talk between different colours.

By providing the colour-conversion quantum dots on or in a porous layer on the optical filter, rather than as part of the LED structures themselves, the present inventors have found that improved stability and reliability of quantum dots may be achieved. This solution also avoids the time-consuming and potentially undesirable requirement to electrochemically porosify and impregnate QDs into parts of the LED structures themselves, as is required by US20200152841A1. The present approach of providing a colour-converting optical filter may therefore advantageously allow wafers or chips of monochromatic LEDs to be converted into multi-colour-emitting devices without requiring electrochemical treatment of the LED chips themselves.

Another benefit of the present invention is that it improves the colour-conversion efficiency achieved by the colour converting material. In prior art designs, some of the light at wavelength λ₁ which is used to excite the colour-conversion material is not absorbed by the colour-conversion material, and simply leaks out of the device. In the present invention however, the DBR reflects the light of wavelength λ₁ back into the LED device, rather than allowing it to be transmitted out of the device through the optical filter. This ensures that the colour converting material (preferably quantum dots) receive much more incident light of wavelength λ₁ to cause excitation of the colour-conversion material. This means that the colour-conversion efficiency of this arrangement is significantly higher than that of prior art devices where colour-conversion quantum dots are simply integrated into the LEDs themselves.

In order for the device to emit at multiple different wavelengths, different colours of colour-conversion material may be coated or impregnated into the porous layer of the optical filter in discrete regions, so that a first colour of colour-conversion material is positioned above a subset of the first portion of the plurality of LEDs, and/or a second colour of colour-conversion material is positioned above another subset of the first portion of the plurality of LEDs.

For example, different colours of colour-conversion quantum dots may be coated or impregnated into the porous layer of the optical filter in discrete regions, so that a first colour of light emitting quantum dots are positioned above a subset of the first portion of the plurality of LEDs, and/or a second colour of light emitting quantum dots are positioned above another subset of the first portion of the plurality of LEDs.

Preferably green colour-conversion material is positioned above a first subset of the first portion of the plurality of LEDs, and/or red colour-conversion material is positioned above a second subset of the portion of the plurality of LEDs, or vice versa. Thus when the first subset of LEDs emits light, that light is converted into green light by the green colour-conversion material, and when the second subset of LEDs emits light, that light is converted into red light by the red colour-conversion material.

Preferably green light emitting quantum dots are positioned above a subset of the first portion of the plurality of LEDs, and/or red light emitting quantum dots are positioned above another subset of the portion of the plurality of LEDs, or vice versa.

The porous layer of the optical filter may comprise a plurality of mesas forming the discrete regions, such that a first set of mesas are impregnated with green colour-conversion material, and/or a second set of mesas are impregnated with red colour-conversion material. The mesas may be formed by electrochemical etching to remove sections of the porous layer to leave discrete plinths or mesas onto which the colour-conversion material may be deposited. The mesas are preferably configured to align with the emission pathway of particular LEDs in the plurality of LEDs, so that light emitted by the desired LED interacts with the colour-conversion material on a particular mesa aligned with that LED, and the colour-conversion material then emits light at a converted wavelength λ₂.

For example the porous layer of the optical filter may comprise a plurality of mesas forming the discrete regions, such that a first set of mesas are impregnated with green light emitting quantum dots, and/or a second set of mesas are impregnated with red light emitting quantum dots. The mesas may be formed by electrochemical etching to remove sections of the porous layer to leave discrete plinths or mesas onto which the QDs may be deposited. The mesas are preferably configured to align with particular LEDs in the plurality of LEDs, so that light emitted by the desired LED interacts with the QDs on a particular mesa aligned with the LED, and the QDs then emit light at a converted wavelength λ₂.

Particles of colour-conversion material may be embedded in the porous layer of the optical filter at a depth of between 1 nm to 200 nm. For example, quantum dots, phosphors, or organic or inorganic perovskites may be embedded in the porous layer of the optical filter at a depth of between 1 nm to 200 nm.

Quantum dots may be embedded in the porous layer of the optical filter at a depth of between 1 nm to 200 nm.

The LED Device may comprise a colour filter material positioned between the colour-conversion material and the DBR. The colour filter material may advantageously protect the colour conversion material (for example the QDs) from sun-light.

Colour filter material may or may not be used, depending on the application of the LED device. If the LED device is intended for use in Augmented Reality glasses or displays in the outdoor settings, for example, colour filter material is preferably incorporated into the LED device in order to protect the colour-conversion material from UV exposure. Colour filter material may alternatively be called UV cut material, which can be any material that absorbs the UV light, but does not prevent the emitted RGB coloured light from being transmitted out of the LED device. The colour filter material may optionally be a different type of colour converting material, such as QDs or any of the colour-conversion materials listed above, which specifically absorbs the UV light from the environment and the sun.

Although blue LEDs, and green and red colour-converting material (preferably QDs) are a particularly preferred embodiment of the present invention, as this combination allows the LED device to emit red, green and blue light, other colour combinations are also possible.

The DBR comprises a stack of layers of semiconductor material, preferably III-nitride semiconductor material, in which alternating layers in the stack have different porosities, and therefore different refractive indices. The alternating refractive indices of the layers cause the DBR to acts as a wavelength-specific mirror which filters out and prevents transmission of the specific wavelength λ₁ while allowing transmission of other wavelengths through the DBR and out of the device. The layers in the DBR stack have a thickness equal to λ₁/4, where λ₁ is the wavelength of light the DBR is configured to filter out. The DBR may therefore be configured to filter out any desired wavelength of light by altering the thickness of the layers.

A preferred process of preparing a DBR made of III-nitride semiconductor material by electrochemical etching is described in WO2019/063957A1.

The III-nitride material is preferably selected from the list consisting of: GaN, AlGaN, InGaN, InAlN, AlInGaN, and AlN.

Using the electrochemical porosification method described in WO2019/063957A1, the porosity of the DBR layers can be varied from 0-100% and pore size can be varied between 10-100 nm using the doping levels or electrochemical conditions such as voltage, current, temperature, etc.

The optical filter preferably comprises an optically transparent substrate layer attached to the DBR, preferably in which the substrate layer is sapphire or glass. When the LED device is assembled, the substrate may form the outermost layer of the device, such that the DBR is positioned between the substrate and the LEDs.

In a preferred embodiment of the present invention there is an LED device, comprising:
a first blue/UV LED positioned beneath the second region of the optical filter, in which the second region of the optical filter is configured to allow transmission of blue/UV light out of the device;
a second blue/UV LED positioned beneath the DBR in the first region of the optical filter, and green colour-conversion material positioned between the second blue/UV LED and the DBR, in which the DBR is configured to prevent the transmission of blue/UV light but to allow the transmission of green light out of the device; and
a third blue/UV LED positioned beneath the DBR in the first region of the optical filter, and red colour-conversion material positioned between the third blue/UV LED and the DBR, in which the DBR is configured to prevent the transmission of blue/UV light but to allow the transmission of red light out of the device.

In a particularly preferred embodiment of the present invention there is an LED device comprising:
a first blue LED positioned beneath the second region of the optical filter, in which the second region of the optical filter is configured to allow transmission of blue light out of the device;
a second blue LED positioned beneath the DBR in the first region of the optical filter, and a plurality of green light emitting colour-conversion quantum dots positioned between the second blue LED and the DBR, in which the DBR is configured to prevent the transmission of blue light but to allow the transmission of green light out of the device; and
a third blue LED positioned beneath the DBR in the first region of the optical filter, and a plurality of red light emitting colour-conversion quantum dots positioned between the third blue LED and the DBR, in which the DBR is configured to prevent the transmission of blue light but to allow the transmission of red light out of the device. The colour-conversion quantum dots are preferably embedded in mesas of a porous III-nitride layer positioned between the LEDs and the DBR.

The LED device may advantageously form an RGB display.

The LED device may be an array of LEDs divided into a plurality of RGB pixels. Thus the first portion of the plurality of LEDs (from which the emitted light at wavelength λ₁ is blocked by the DBR) is made up of the green and red pixels, while the second portion of the plurality of LEDs act as the blue pixels.

In a preferred embodiment, the plurality of LEDs form part of a CMOS blue LED wafer. The optical filter may be mounted upon the LED wafer to form the LED device of the present invention.

In a second aspect of the present invention there is provided an optical filter for an LED device comprising a plurality of light-emitting diodes (LEDs), the optical filter comprising: a first region arranged to filter light emitted from a first portion of the plurality of LEDs, in which the first region of the optical filter comprises a Distributed Bragg Reflector (DBR) configured to prevent transmission of light of a predetermined wavelength λ₁.

The optical filter preferably comprises a second region arranged to transmit light of the predetermined wavelength λ₁ emitted from a first portion of the plurality of LEDs.

The optical filter is preferably an optical filter as described above in relation to the first aspect of the invention. The features of the optical filter described above therefore apply equally to the optical filter of the second aspect.

The optical filter preferably comprises a porous layer of material adjacent the DBR.

The porous layer is covered or impregnated with a colour-conversion material.

The colour conversion material may be colour-conversion quantum dots, phosphors, or organic or inorganic perovskites.

As described in relation to the first aspect, the porous layer may be formed from porous semiconductor material or porous dielectric material, but in a particularly preferred embodiment the porous layer is formed from porous III-nitride material.

In a preferred embodiment, the first region of the optical filter comprises a porous layer of III-nitride material positioned between the LEDs and the DBR. The porous layer of III-nitride material may be electrochemically porosified using the technique described in WO2019/063957A1. Preferably the porous layer of III-nitride material is coated or impregnated with colour-conversion material, for example colour-converting quantum dots.

By providing the colour-conversion quantum dots on or in a porous layer (preferably of III-nitride material) on the optical filter, rather than as part of the LED structures themselves, the present inventors have found that improved stability and reliability of quantum dots may be achieved. This solution also avoids the time-consuming and potentially undesirable requirement to electrochemically porosify and impregnate parts of the LED structures themselves, as is required by US20200152841A1. The present approach of providing a colour-converting optical filter may therefore advantageously allow wafers or chips of monochromatic LEDs to be converted into multi-colour-emitting devices without requiring electrochemical treatment of the LED chips themselves.

The present invention has the significant benefits that compared to prior art alternatives for colour-converting LEDs, the processing steps required to form the optical filter of the present invention are simpler and independent of the LED chips themselves. And the optical filter combination of QDs plus porous layer plus DBR is multifunctional, for blocking blue/UV light as much as possible, for recycling blue/UV light as much as possible to enhance colour conversion efficiency, and for porous encapsulation of QDs to improve the stability and reliability of QDs.

In order for the device to emit at multiple different wavelengths, different colours of colour-conversion material (for example light emitting quantum dots) may be coated or impregnated into the porous layer of the optical filter in discrete regions, so that a first colour of colour-conversion material is positioned above a subset of the first portion of the plurality of LEDs, and/or a second colour of colour-conversion material is positioned above another subset of the portion of the plurality of LEDs.

Preferably green colour-conversion material is positioned above a subset of the first portion of the plurality of LEDs, and/or red colour-conversion material is positioned above another subset of the portion of the plurality of LEDs, or vice versa.

Preferably green light emitting quantum dots are positioned above a subset of the first portion of the plurality of LEDs, and/or red light emitting quantum dots are positioned above another subset of the portion of the plurality of LEDs, or vice versa.

The porous layer of the optical filter may comprise a plurality of mesas forming the discrete regions, such that a first set of mesas are impregnated with green colour-conversion material, and/or a second set of mesas are impregnated with red colour-conversion material. The mesas may be formed by electrochemical etching to remove sections of the porous layer to leave discrete plinths or mesas onto which the QDs may be deposited. The mesas are preferably configured to align with particular LEDs in the plurality of LEDs, so that light emitted by the desired LED interacts with the colour-conversion material on a particular mesa aligned with the LED, and the colour-conversion material then emits light at a converted wavelength λ₂.

The porous layer of the optical filter may comprise a plurality of mesas forming the discrete regions, such that a first set of mesas are impregnated with green light emitting quantum dots, and/or a second set of mesas are impregnated with red light emitting quantum dots. The mesas may be formed by electrochemical etching to remove sections of the porous layer to leave discrete plinths or mesas onto which the QDs may be deposited. The mesas are preferably configured to align with particular LEDs in the plurality of LEDs, so that light emitted by the desired LED interacts with the QDs on a particular mesa aligned with the LED, and the QDs then emit light at a converted wavelength λ₂.

Particles of colour-conversion material may be embedded in the porous layer of the optical filter at a depth of between 1 nm to 200 nm.

Quantum dots may be embedded in the porous layer of the optical filter at a depth of between 1 nm to 200 nm.

In a third aspect of the invention there is provided an optical filter for an LED device comprising a plurality of light-emitting diodes (LEDs), the optical filter comprising:
a Distributed Bragg Reflector (DBR) configured to prevent transmission of light of a predetermined wavelength λ₁,
and a porous layer of material adjacent the DBR,
in which the porous layer is covered or impregnated with a colour-conversion material.

The optical filter may comprise further layers of material between the DBR and the porous layer of material. The optical filter may also comprise further layers of material (preferably III-nitride material) between the porous layer and the LED-facing surface of the optical filter.

As described in relation to the other aspects, the porous layer may be formed from porous semiconductor material or porous dielectric material, but in a particularly preferred embodiment the porous layer is formed from porous III-nitride material.

The porous layer is preferably a surface layer of the optical filter. The optical filter may be configured so that the DBR is positioned between the porous layer and a substrate.

The colour conversion material may be colour-conversion quantum dots, phosphors, or organic or inorganic perovskites.

The colour-conversion material may preferably be red-emitting and/or green-emitting. For example, the colour-conversion quantum dots may be red-emitting and/or green-emitting.

In order for the optical filter to allow an LED device to emit at multiple different wavelengths, different colours of colour-conversion material may be coated or impregnated into the porous layer of the optical filter in discrete regions, so that a first colour of light emitting quantum dots are positioned above a subset of the first portion of the plurality of LEDs, and/or a second colour of light emitting quantum dots are positioned above another subset of the portion of the plurality of LEDs.

Preferably green colour-conversion material is positioned above a first subset of the first portion of the plurality of LEDs, and/or red colour-conversion material is positioned above a second subset of the portion of the plurality of LEDs, or vice versa.

Preferably green light emitting quantum dots are positioned above a subset of the first portion of the plurality of LEDs, and/or red light emitting quantum dots are positioned above another subset of the portion of the plurality of LEDs, or vice versa.

The porous III-nitride layer of the optical filter may comprise a plurality of mesas forming the discrete regions, such that a first set of mesas are impregnated with green light emitting quantum dots, and/or a second set of mesas are impregnated with red light emitting quantum dots. The mesas may be formed by electrochemical etching to remove sections of the III-nitride layer to leave discrete plinths or mesas onto which the QDs may be deposited. The mesas are preferably configured to align with particular LEDs in the plurality of LEDs, so that light emitted by the desired LED interacts with the QDs on a particular mesa aligned with the LED, and the QDs then emit light at a converted wavelength λ₂.

The colour-conversion material may remain only on the surface of the optical filter or may be embedded into the optical filter.

The colour-conversion material may remain only on the surface or may be embedded into the porous layer. The depth of quantum dot incorporation can be between 1 nm-200 nm.

The optical filter may comprise a colour filter material positioned between the colour-conversion material and the DBR, as described above in relation to the first aspect. The colour filter material may advantageously protect the colour conversion material (for example the QDs) from sun-light.

The optical filter may comprise an encapsulation layer forming a surface layer of the optical filter. The encapsulation layer may be, for example, epoxy or silicone based material.

The optical filter preferably comprises an optically transparent substrate layer attached to the DBR, preferably in which the substrate layer is sapphire or glass. When the LED device is assembled, the substrate may form the outermost layer of the device, such that the DBR is positioned between the substrate and the LEDs.

Alternatively, the substrate on the optical filter can either be removed or thinned or polished, to arrive at desired optical emission characteristics.

The complete structure of the optical filter will provide the benefit of a high-reflectivity porous DBR for quantum dot excitation, while at the same time blocking any light of wavelength λ₁ (preferably blue light) from passing through the transparent substrate.

The porous layer of III-nitride material can act as an encapsulation or matrix housing for the colour converting nanoparticles, which will improve the stability, reliability, and lifetime of the quantum dots. The porous layer can also act as a template for crystallisation of different precursors, where nanocrystals can be formed within the porous layer. Meanwhile, nanocrystals, nanoparticles can be infiltrated into the porous layer, by spincoating or soaking followed by heat/annealing treatment.

The porous layer of III-nitride material can also act as a scattering medium to allow the colour converting nanocrystal/nanostructures to have higher colour conversion efficiency when pumped.

The DBR is preferably a porous DBR comprising a stack of layers of III-nitride material. The DBR can act as an optical filter which can filter out the UV or blue light of a desired wavelength λ₁, and transmit as much as possible of the converted colour, green and red, i.e. porous DBR was designed so that UV/blue has very high reflectivity, but green and red have the highest transmission.

The features of the optical filter are described above in relation to the other aspects of the invention.

In a fourth aspect of the invention there may be provided a method of manufacturing an optical filter according to the present invention, the method comprising the steps of:
forming a DBR by electrochemically porosifying a multi-layer stack of III-nitride semiconductor material, and
covering or impregnating at least a first portion of the optical filter with a colour-conversion material.

The method of manufacturing an optical filter according to the present invention may comprise the steps of:
forming a DBR by electrochemically porosifying a multi-layer stack of III-nitride semiconductor material,
forming a porous layer adjacent, or over, the DBR, and
covering or impregnating at least a first portion of the porous layer with a colour-conversion material.

The porous layer may be formed over the DBR. One or more additional layers, preferably of III-nitride material, may be formed between the porous layer and the DBR.

The colour-conversion material is preferably colour conversion quantum dots, and the DBR preferably prevents transmission of light at a predetermined wavelength λ₁ as described above in relation to the other aspects of the invention.

The method may comprise the step of etching the porous layer into a plurality of mesas.

The step of covering or impregnating the porous layer with a colour conversion material may comprise the steps of covering or impregnating one or more discrete regions of the porous layer, or a subset of the mesas of the porous layer, with a colour-conversion material of a first colour. Also the step of covering or impregnating one or more other discrete regions of the porous layer, or a different subset of the mesas of the porous layer, with a colour-conversion material of a second colour.

The porous layer may be a layer of III-nitride material, and the porous layer and the DBR are preferably formed using the electrochemical porosification method described in WO2019/063957A1. In one option, the porous layer may be grown and porosified first, before the DBR stack is grown and in the same structure and porosified, but it could be the other way around. Alternatively the DBR stack may be epitaxially grown and porosified first, following by overgrowing an n+ doped III-nitride layer, for example n+GaN, and then porosifying the n+ doped III-nitride layer to make it porous.

The method of manufacture may comprise the step of masking a first region of the porous layer and DBR, and removing a second region of the porous layer and DBR by etching. The removed region of the DBR may then allow transmission of the predetermined wavelength λ₁ that is blocked by the DBR. This is typically done before colour-conversion material is applied to the porous layer. No colour-conversion material is applied to the second region of the optical filter.

Normal wafer processing steps of masking, lithographic etching, and patterning are usable to create the second region on already-formed porous layer and DBR wafer, where the positions of the second region or regions are matched with the positions of the second portion of the plurality of LEDs. Alternatively, masking and patterning can be done on the epiwafer first, then porosification, followed by QD impregnation.

Alternatively, the optical filter may be epitaxially grown as a semiconductor structure with a multi-layer stack of III-nitride material in a first region, and a non-layered second region, such that electrochemical porosification of the structure porosifies the stack to form a DBR, while the second region remains optically transparent to light of wavelength λ₁. This may be done by pre-patterning the wafer, and then growing a DBR stack on the first region and a non-stack semiconductor structure on the second region selectively, and then porosifying the structure to have a porous layer and DBR in the first region, and no porous layer and no DBR in the second region.

A black matrix formed from masking material such as black epoxy or photo imageable dielectric material may be deposited on the surface of the DBR, or of a layer of III-nitride material positioned over the DBR. The black matrix may then be patterned to expose a plurality of exposed regions on the DBR to allow light to pass through the optical filter.

The method may comprise the step of depositing a colour filter material in the exposed regions.

The green and red colour-conversion materials may then be deposited over the colour filter material.

A protective encapsulation layer may be formed over the optical filter after the colour-conversion material has been applied.

The method may optionally comprise the steps of removing, thinning or polishing a substrate on which the optical filter has been grown.

According to a further aspect of the invention there may be provided a method of manufacturing LED device comprising a plurality of LEDs and an optical filter according to the present invention.

The method may comprise the steps of forming an optical filter, as described above, and mounting the optical filter above a plurality of LEDs, so that the light emitted by a first portion of the plurality of LEDs interacts with the colour-conversion material. The LEDs are preferably monochromatic LEDs with a transmission wavelength λ₁, and the colour conversion material preferably converts this emitted light into light with a converted wavelength λ₂. The DBR prevents transmission of light of wavelength λ₁ from the first plurality of LEDs, so that only the converted wavelengths λ₂ of light are transmitted out of the first region of the LED device. This advantageously prevents blue light leakage from the first region when only converted wavelengths are desired.

The method may comprise the step of arranging the first region of the optical filter, which prevents transmission of light at the LEDs' emission wavelength λ₁, above a first portion of the plurality of LEDs, so that light of wavelength λ₁ emitted by the first portion of LEDs cannot pass out of the LED device.

The method may comprise the step of arranging a second region of the optical filter, which allows transmission of light at the LEDs' emission wavelength λ₁, above a second portion of the plurality of LEDs, so that light of wavelength λ₁ can pass out of the LED device through the second region.

The method may thus provide red, green and blue pixels. Where the LEDs are blue LEDs, blue light can pass out of the device through the second region of the optical filter, while green and red colour-converting material converts the light emitted from the first portion of the LEDs into green and red light respectively, which can be transmitted out of the device through the DBR, while un-converted blue light from the first portion of the LEDs is blocked by the DBR.

In a fifth aspect of the invention there is provided a use of an optical filter according to the first aspect of the invention to convert a plurality of monochromatic LEDs into an LED device for emitting light of a plurality of different colours. Preferably the optical filter may be used to convert monochromatic blue light from a plurality of blue-emitting LEDs into an LED device which comprises red, green and blue pixels.

In a sixth aspect of the invention there may be provided an LED device, comprising:
a plurality of light-emitting diodes (LEDs), and
an optical filter arranged to filter light emitted by the plurality of LEDs,
in which the optical filter comprises a porous region arranged to filter light emitted from a first portion of the plurality of LEDs, in which at least a portion of the porous region is coated or impregnated with colour-conversion material.

The colour-conversion material is preferably configured to absorb light at the emission wavelength λ₁ of the LEDs, and to re-emit light at a converted wavelength λ₂. Instead of light being emitted from the LED device at λ₁, the colour-conversion material therefore causes light to be emitted from the LED device at a different wavelength λ₂.

The colour conversion material may be colour-conversion quantum dots, phosphors, or organic or inorganic perovskites.

The colour-conversion material may preferably be red-emitting and/or green-emitting.

The porous region may be a porous layer, or a porous region in a layer of non-porous semiconductor material. Preferably the porous region is porous III-nitride material.

The porous region may comprise a porous surface, or the porous region may be covered by a non-porous region so that the porous region is a sub-surface porous region.

The LED device may comprise one or more further layers of semiconductor material, preferably III-nitride material, between the colour conversion material and the LEDs.

By providing the colour-conversion material on or in a porous region of the optical filter, rather than as part of the LED structures themselves, the present inventors have found that improved stability and reliability of colour-conversion material such as quantum dots may be achieved. This solution also avoids the time-consuming and potentially undesirable requirement to electrochemically porosify and impregnate QDs into parts of the LED structures themselves, as is required by US20200152841A1. The present approach of providing a colour-converting optical filter may therefore advantageously allow wafers or chips of monochromatic LEDs to be converted into multi-colour-emitting devices without requiring electrochemical treatment of the LED chips themselves.

The optical filter may comprise a first region which comprises a Distributed Bragg Reflector (DBR) configured to prevent transmission of light of a predetermined wavelength λ₁ from the first portion of the plurality of LEDs. The DBR is preferably a III-nitride DBR formed from alternating layers of III-nitride material having different porosities, preferably alternating porous and non-porous layers.

The DBR is preferably positioned between the first portion of the plurality of LEDs and the outlet through which emitted light exits the LED device, so that the DBR is arranged to filter light emitted by the first portion of the plurality of LEDs.

The use of a DBR reflecting at the emission wavelength λ₁ of the LEDs may advantageously improve the colour-conversion efficiency achieved by the colour converting material. In prior art designs, some of the light at wavelength λ₁ which is used to excite the colour-conversion material is not absorbed by the colour-conversion material, and simply leaks out of the device. When a DBR is used in the optical filter, however, the DBR reflects the light of wavelength λ₁ back into the LED device, rather than allowing it to be transmitted out of the device through the optical filter. This ensures that the colour converting material (preferably quantum dots) receive much more incident light of wavelength λ₁ to cause excitation of the colour-conversion material. This means that the colour-conversion efficiency of this arrangement is significantly higher than that of prior art devices where colour-conversion quantum dots are simply integrated into the LEDs themselves.

The LED device preferably comprises sections of masking material, or black matrix material, configured to separate pixel areas on the optical filter.

Preferably a first portion of the porous region is coated or impregnated with a first colour-conversion material, and a second portion of the porous region is coated or impregnated with a second colour-conversion material. The first colour-conversion material may preferably be green, and the second colour-conversion material may preferably be red.

A first colour-conversion material is preferably positioned over a first subset of LEDs in the first portion of the plurality of LEDs. Thus light emitted by the first subset of LEDs in the first portion of the plurality of LEDs may be colour-converted by the first colour-conversion material before it is transmitted out of the device.

A second colour-conversion material is preferably positioned over a second subset of LEDs in the first portion of the plurality of LEDs. Thus light emitted by the second subset of LEDs in the first portion of the plurality of LEDs may be colour-converted by the second colour-conversion material before it is transmitted out of the device.

The optical filter preferably comprises a second region arranged to filter light emitted from a second portion of the plurality of LEDs. The second region of the optical filter preferably allows transmission of light of wavelength λ₁. The second region may, however, be configured to reduce the brightness of light of wavelength λ₁ transmitted from the second portion of the plurality of LEDs, so that the light emitted out of the device from the second region is not significantly brighter than the light emitted from the first region.

Preferably no colour-conversion material is positioned over the second plurality of LEDs, so that the light transmitted through the second region of the optical filter is not colour-converted.

The plurality of LEDs are preferably monochromatic LEDs, particularly preferably monochromatic blue LEDs or UV LEDs. Preferably all of the LEDs in the plurality of LEDs emit at the same wavelength.

In an alternative embodiment, the plurality of LEDs may comprise a portion of LEDs that emit light at a first wavelength, and a portion of LEDs that emit light at a second wavelength different from the first wavelength.

The plurality of LEDs may comprise monochromatic LEDs or panchromatic LEDs. The emission wavelength of the LEDs is preferably λ₁.

The LED device may optionally comprise a colour filter material and/or a protective encapsulation layer, as described above.

The LED device may be an array of LEDs divided into a plurality of RGB pixels. Thus the first portion of the plurality of LEDs (from which the emitted light at wavelength λ₁ is converted by green and red colour-conversion material into green and red wavelengths) is made up of the green and red pixels, while the second portion of the plurality of LEDs act as the blue pixels.

The LED device may advantageously form an RGB display.

In a seventh aspect of the invention there may be provided an optical filter for an LED device comprising a plurality of light-emitting diodes (LEDs), the optical filter comprising: a porous region arranged to filter light emitted from a first portion of the plurality of LEDs, in which at least a portion of the porous region is coated or impregnated with colour-conversion material.

The optical filter may have any of the features of the optical filter described above in relation to any other aspect of the invention, in particular the second or sixth aspects of the invention.

The LED device preferably comprises sections of masking material, or black matrix material, configured to separate pixel areas on the optical filter.

Preferably a first portion of the porous region is coated or impregnated with a first colour-conversion material, and a second portion of the porous region is coated or impregnated with a second colour-conversion material. The first colour-conversion material may preferably be green-emitting, and the second colour-conversion material may preferably be red-emitting.

The first portion of the porous region and the first colour-conversion material are preferably configured to be positioned over a first subset of LEDs in the first portion of the plurality of LEDs. Thus light emitted by the first subset of LEDs in the first portion of the plurality of LEDs is colour-converted by the first colour-conversion material before it is transmitted out of the filter.

The second portion of the porous region and the second colour-conversion material are preferably configured to be positioned over a second subset of LEDs in the first portion of the plurality of LEDs. Thus light emitted by the second subset of LEDs in the first portion of the plurality of LEDs is colour-converted by the second colour-conversion material before it is transmitted out of the filter.

The optical filter may comprise a first region which comprises a Distributed Bragg Reflector (DBR) configured to prevent transmission of light of a predetermined wavelength λ₁ from the first portion of the plurality of LEDs. The DBR may thus filter out light of wavelength λ₁ emitted by the first portion of the plurality of LEDs, preventing it from passing through the filter and out of any device into which the filter is integrated.

The optical filter preferably comprises a second region arranged to filter light emitted from a second portion of the plurality of LEDs. The second region of the optical filter preferably allows transmission of light of wavelength λ₁. The second region may, however, be configured to reduce the brightness of light of wavelength λ₁ transmitted from the second portion of the plurality of LEDs, so that the light emitted out of the device from the second region is not significantly brighter than the light emitted from the first region.

Preferably the second region of the optical filter is not coated with or impregnated with colour-conversion material, so that the light transmitted through the second region of the optical filter is not colour-converted.

According to a further aspect of the invention, there may be provided a method of forming an LED device comprising a plurality of light-emitting diodes (LEDs) and
an optical filter, comprising the steps of forming the plurality of LEDs, and then forming, over the plurality of LEDs, an optical filter according to any preceding aspect of the invention, so that the optical filter is configured to filter light emitted by the plurality of LEDs.

According to a further aspect of the invention, there may be provided a method of forming an LED device comprising a plurality of light-emitting diodes (LEDs) and
an optical filter arranged to filter light emitted by the plurality of LEDs, comprising the steps of forming an optical filter according to any preceding aspect of the invention, and then forming, over the optical filter, a plurality of LEDs configured to emit light through the optical filter.

In either of these methods, instead of forming the optical filter and the LEDs separately, and then flipping and bonding the filter to the LED chip, the optical filter may alternatively be formed epitaxially over the LED chip (or vice versa).

The features of the optical filter and the LED device are described above in relation to the preceding aspects of the invention. In order to form these components integrally with one another, the component parts of the LEDs and the optical filter may be deposited in sequential layers, using conventional masking and epitaxial growth techniques, as will be clear to one of skill in the art.

The features described above in relation to one aspect of the invention are equally applicable to the same features in the contexts of the other aspects of invention.

### BRIEF DESCRIPTION OF THE DRAWINGS

Specific embodiments of the invention will now be described with reference to the figures, in which:

FIG. 1 shows a schematic side-on cross-section of an optical filter according to an embodiment of the present invention;

FIG. 2 shows a schematic side-on cross-section of an optical filter coated with colour-converting material, according to an embodiment of the present invention;

FIG. 3 shows a schematic side-on cross-section of an optical filter impregnated with colour-converting material, according to an embodiment of the present invention;

FIG. 4 shows a schematic side-on cross-section of an optical filter coated with colour-converting material, according to another preferred embodiment of the present invention; and

FIG. 5 shows a schematic side-on cross-section of the optical filter of FIG. 4 incorporated into an LED device, according to an aspect of the present invention;

FIG. 6 shows a schematic side-on cross-section of an optical filter coated with colour-converting material, according to an exemplary embodiment of the present invention;

FIG. 7 shows a schematic side-on cross-section of the optical filter of FIG. 6 incorporated into an LED device, according to an aspect of the present invention;

FIG. 8 shows a schematic side-on cross-section of an LED device comprising an optical filter, according to an aspect of the present invention;

FIG. 9 is a graph of reflectance vs wavelength measured for five optical filters embodying the present invention;

FIG. 10 is a photograph illustrating a comparison of the performance of colour-converting materials on glass, and the same colour-converting materials provided on a porous/non-porous DBR as used in preferred embodiments of the present invention;

FIG. 11A is a graph of photoluminescence (PL) intensity vs wavelength for green QDs on glass, excited by a 450 nm excitation laser;

FIG. 11B is a graph of photoluminescence (PL) intensity vs wavelength for green QDs on a porous optical filter of the present invention, excited by a 450 nm excitation laser;

FIG. 12A is a graph of photoluminescence (PL) intensity vs wavelength for red QDs on glass, excited by a 450 nm excitation laser; and

FIG. 12B is a graph of photoluminescence (PL) intensity vs wavelength for red QDs on a porous optical filter of the present invention, excited by a 450 nm excitation laser.

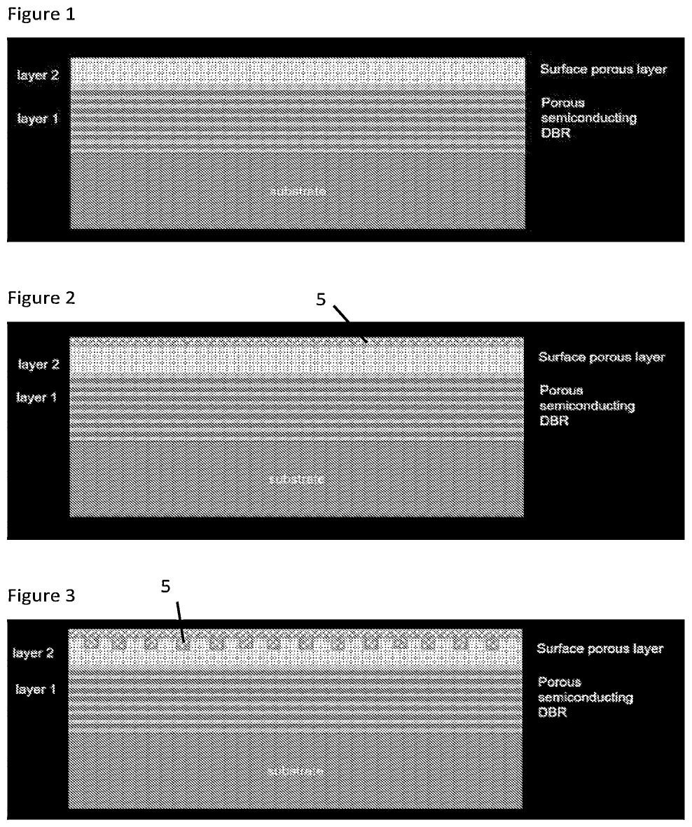

FIG. 1 shows a porous DBR formed from III-nitride semiconductor material (labelled layer 1), and a surface porous layer (labelled layer 2), fabricated on an optically transparent (350-700 nm) or non-transparent substrate. The substrate can be sapphire, glass etc.

This could be implemented via direct growth of III-nitrides layers onto the substrate followed by electrochemical porosification of the layered III-nitride structure, or via transfer of porosified III-nitride layers to a ‘host substrate’, where the host substrate is optically transparent.

In one example, the porous stack is designed to filter out blue light coming from the epi surface (the uppermost surface of the structure as shown). In practice, such a porous/non-porous stack can be designed for different purposes for reflection or transmission of any colour or colour mixture by varying the thicknesses of the DBR layers to reflect a selected wavelength of light.

DBR (Layer 1) Info:

The DBR is formed from a stack of porous (Al,In)GaN/non-porous (Al,In)GaN, where the thicknesses are designed so that certain wavelengths of the light can be reflected or transmitted, whilst other colours/wavelengths can be transmitted or reflected, respectively. In layer 1, each porous layer was porosified using electrochemical porosification from a highly doped (Al,In)GaN layer with a pre-porosification doping level between 1×10¹⁸-1×10²⁰ cm⁻³, using the known technique set out in WO2019/063957A1. Alternating non-porous layers of the DBR are formed from (Al,In)GaN layers in which the pre-porosification doping has to be less than 1×10¹⁸ cm⁻³, so that there is sufficient doping contrast from the layers which will be porosified.

To form the DBR (layer 1), the porous and non-porous layers' thicknesses have to fill quarter lambda of the wavelength desired to be blocked (reflected back into the LED device, rather than transmitted through the DBR and out of the device through the substrate) to allow desirable reflection or transmission to occur. Layer 1's porosity can be varied from 0-100% and pore size can be varied between 10-100 nm using the doping levels or electrochemical conditions such as voltage, current, temperature, etc.

Porous Surface Layer (Layer 2) Info:

The thickness of the surface porous layer can be between 1 nm-5000 nm. This layer can be formed from III-nitride semiconductor material or other semiconductors or other materials (i.e. dielectric material).

The doping level in layer 2 can be between 1×10¹⁸-1×10²⁰ cm⁻². After porosification the porosity can vary between 0.1-100%, and the pore size in layer 2 can vary between 10-100 nm.

FIG. 2 shows the optical filter of FIG. 1, with a coating of colour-conversion material on the uppermost surface of the porous layer (layer 2).

In use with a plurality of LEDs, the optical filter will be arranged above the filter as illustrated, so that LED light is incident on the porous layer coated with colour-conversion material, so that the optical filter allows certain wavelengths of light to be transmitted through the layers and out through the substrate, while one or more predetermined wavelengths are reflected by the DBR and prevented from passing out of the device.

In FIG. 2, the optical filter comprises the stack of porous DBR with well-defined optical filtering properties, along with a surface porous III-nitride layer which is covered with quantum dots, phosphors, or organic or inorganic perovskites.

FIGS. 2 and 3 show an embodiment in which the colour-conversion material is a plurality of colour-conversion quantum dots 5.

The quantum dots can be green or red emitting.

The quantum dots 5 may remain only on the surface of the porous layer as shown in FIG. 2, or they may be embedded into the porous layer 2 as shown in FIG. 3.

The depth of quantum dot incorporation into the porous layer can be between 1 nm-200 nm.

The complete structure of FIGS. 2 and 3 will provide the benefit of high reflectivity porous DBR for quantum dot excitation. By reflecting light of a predetermined wavelength λ₁ back into the device, rather than allowing it to be transmitted out of the optical filter through the substrate, the DBR ensures that the colour converting material (preferably quantum dots) receive much more incident light to cause excitation of the quantum dots. This means that the colour-conversion efficiency of this arrangement is significantly higher than that of prior art devices where colour-conversion quantum dots are simply integrated into the LEDs themselves.

The DBR has the additional benefit that it also blocks transmission of any blue light of Al passing out of the optical filter through the transparent substrate. This means that only the converted-colour light from the colour-conversion material is transmitted through the optical filter.

The optical filter therefore:
increases the colour-conversion efficiency to increase the brightness of colour-converted (red and green) light emitted from an LED device; and
reduces colour cross-talk by preventing non-converted-wavelength light at wavelength λ₁ from being transmitted out of the optical filter.

The porous layer 2 can act as an encapsulation or matrix housing for the colour converting nanoparticles, which will improve the stability, reliability, and lifetime. The porous layer 2 can also act as a template for crystallisation of different precursors, where nanocrystals can be formed within the porous layer 2. Meanwhile, nanocrystals, nanoparticles can be infiltrated into porous layer 2, by spincoating or soaking followed by heat/annealing treatment.

Porous layer 2 can also act as a scattering medium to allow the colour converting nanocrystal/nanostructures to have higher colour conversion efficiency when pumped.

The porous DBR (layer 1) can act as an optical filter which can filter out the non-converted wavelengths (preferably UV or blue light), and transmit as much as possible of the converted colours, such as green and red.

The thickness of the layers in the porous DBR are preferably selected so that UV/blue has very high reflectivity, but green and red have the highest transmission through the DBR.

The DBR may be configured to reflect more than one predetermined wavelength.

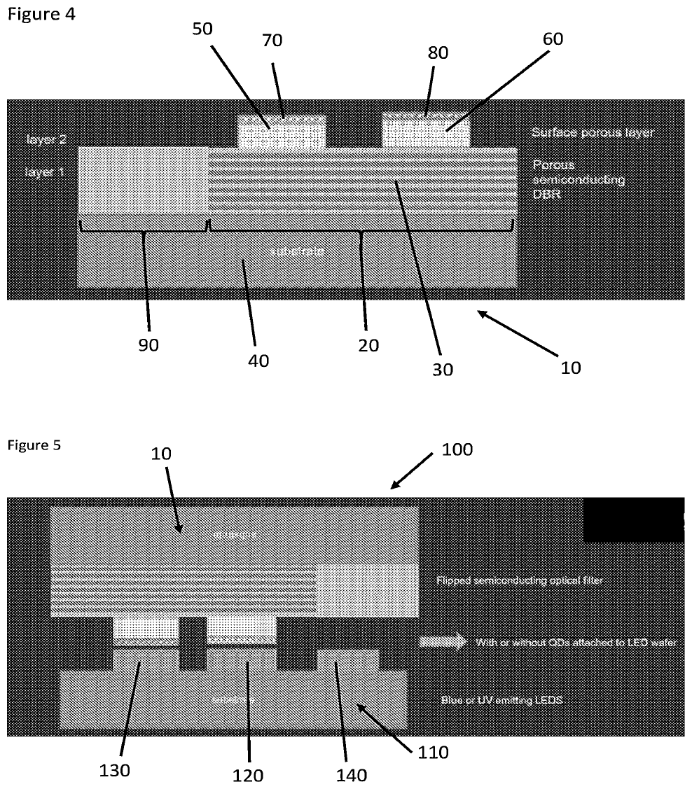

FIG. 4 shows a particularly preferred embodiment of an optical filter which is suitable for converting a plurality of monochromatic LEDs into a multi-colour display, preferably one with red, green and blue pixels.

The optical filter 10 of FIG. 4 comprises a first region 20 in which a DBR 30 covers an area of the transparent substrate 40. The DBR is designed to reflect blue light, so that blue light cannot pass through the first region 20 and out of the substrate 40. On the uppermost surface (the surface opposite the substrate) of the DBR there are two mesas 50, 60 of porous material. A first mesa 50 of porous material is impregnated with green-emitting colour-conversion quantum dots 70, while a second mesa 60 of porous material is impregnated with red-emitting colour-conversion quantum dots 80.

The mesas 50 may be formed by masking and electrochemically etching away sections of the porous layer of FIG. 1, for example.

Adjacent to the DBR 30, the optical filter 10 also comprises a second region 90 which covers an area of the transparent substrate 40. The second region does not comprise a DBR, and is configured to allow transmission of blue light. The second region may be formed from a semiconductor material which is optically transparent, or partially optically transparent, to blue light. Preferably the second region is formed from III-nitride semiconductor material which may be deposited epitaxially on the substrate.

FIG. 5 shows the optical filter of FIG. 4 incorporated into an LED device 100, according to a particularly preferred embodiment of the present invention.

In the simplified illustrated embodiment, the LED device 100 is formed from the optical filter 10 and an LED chip 110. The LED chip 110 comprises three blue-emitting LEDs on a substrate, though the same principle may be applied to larger arrays of LEDs.

The optical filter 10 can be integrated into the LED device 100 by flipping the orientation of the optical filter 10 so that the porous mesas 50, 60 face the LEDs on the LED chip 110. The optical filter 10 and the LED chip 110 are aligned so that the first mesa 50 is aligned with a first blue LED 120, the second mesa 60 is aligned with a second blue LED 130, and the second region 90 of the optical filter is aligned with a third blue LED 140.

When the LED chip is turned on, all three LEDs 120, 130, 140 emit blue light.

The blue light of the third LED 140 is transmitted through the second region 90 of the optical filter, and passes out of the LED device 100 through the transparent substrate.

The blue light emitted by the first LED 120 is incident on the green colour-conversion quantum dots 70, so that the quantum dots are excited and emit green light. The DBR reflects any blue light which is not absorbed by the quantum dots, and prevents the blue light from passing through the first region 90 of the optical filter. The DBR does not reflect green light, so the colour-converted green light is transmitted out of the optical filter 10 through the DBR and through the substrate, so that the first LED 120 appears to a viewer to be a green LED, or a green pixel.

Similarly, the blue light emitted by the second LED 130 is incident on the red colour-conversion quantum dots 80, so that the quantum dots are excited and emit red light. The DBR reflects any blue light which is not absorbed by the quantum dots, and prevents the blue light from passing through the first region 20 of the optical filter. The DBR does not reflect red light, so the colour-converted red light is transmitted out of the optical filter 10 through the DBR and through the substrate 40, so that the second LED 130 appears to a viewer to be a red LED, or a red pixel.

The optical filter 10 therefore converts an array of blue LEDs into effectively a set of red, green and blue pixels. The DBR prevents blue light leakage through the first region, which improves the colour-conversion efficiency of the quantum dots, and prevents colour cross-talk between pixels. The second region of the filter, however, still allows blue light from one of the blue LEDs to be transmitted out of the LED device.

By using this arrangement, and providing the colour-conversion material on an optical filter, the optical filter of the present invention may advantageously be integrated with blue LED chips or wafers post-production, and without requiring treatment of the LED wafers themselves. This kind of optical filter can therefore be used for direct integration with CMOS blue LED wafer for RBG (red-blue-green) display.

The illustrated three-LED set may be incorporated into a large display comprising a plurality of red, green and blue pixel sets as shown in FIG. 5.

The LEDs described throughout this application may be micro-LEDs.

In an alternative embodiment, the QDs can be coated onto the LED chips with blue or green emission and the semiconducting optical filter may be provided without any QDs. In this embodiment the first and second regions of the optical filter will still give significant benefits with respect to colour-conversion-efficiency and the brightness of the converted colours.

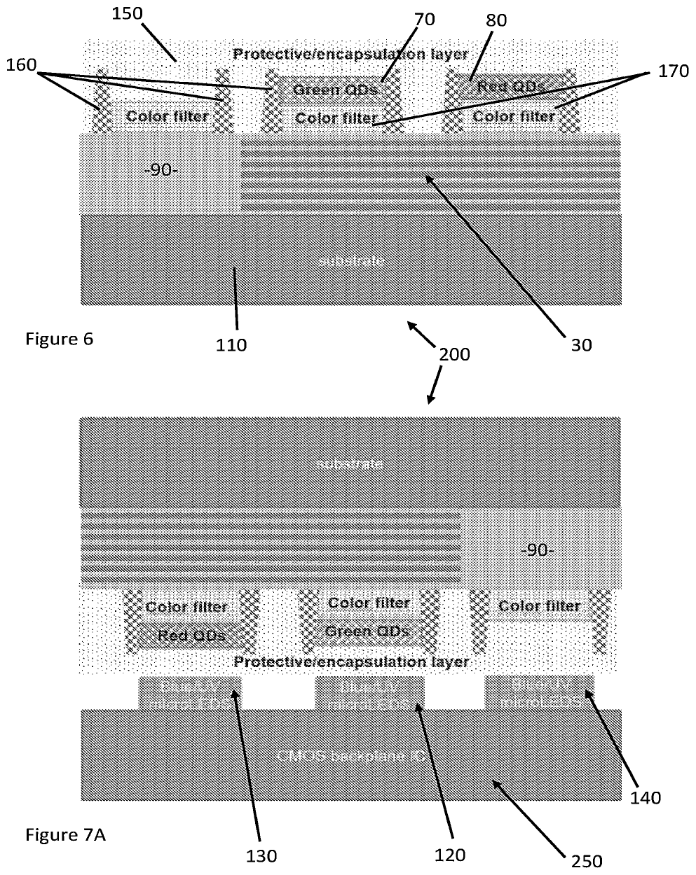

FIG. 6 shows a schematic side-on cross-section of an optical filter 200 coated with colour-converting material, according to an exemplary embodiment of the present invention.

The optical filter 200 of FIG. 6 is manufactured using the following method steps:
1. Selective area electrochemical etch (ECE) porosification, or uniform area ECE porosification, to create a porous DBR 30 and a non-DBR second portion 90 on a substrate 110. As described above, methods of forming porous/non-porous III-nitride DBRs using ECE techniques are known in the art. The position, shape and size of the DBR can be determined by controlling the epitaxial design of the semiconductor material on the substrate, as only n+ doped III-nitride material will be porosified. Conventional masking and/or etching steps may be carried out to limit the DBR to selective areas of the substrate.
2. Deposit the Black Matrix 160, which is typically black epoxy or Photo imageable dielectric. Pattern the black matrix to expose three pixel areas of the optical filter, two of which are over the DBR 30, and one of which is over the non-DBR second portion 90, so that the three pixel areas will be aligned above three LEDs. Portions of black matrix 160 remain to separate adjacent pixel areas, in order to avoid cross-talk between different pixels in operation.
3. A colour filter material 170 may optionally be deposited in all pixel areas on the optical filter.
4. Green and Red QDs 70, 80, or other colour-converting materials, are deposited in the two pixel areas positioned over the DBR (over the colour filter material 170 if it is present). No colour conversion material is deposited in the pixel area that is not positioned over the DBR. Colour-conversion material may be coated onto the colour filter material, or a porous layer may be deposited over the colour filter material, with the colour-conversion material then deposited on or impregnated into the porous layer.
5. Finally, a protective or encapsulation layer 150 is deposited over the top of the optical filter, to protect the components of the filter from damage.

FIGS. 7A and 7B shows schematic side-on cross-sections of the optical filter 200 of FIG. 6 incorporated into an LED device, according to an aspect of the present invention.

In order to form the LED device of FIG. 7A, the optical filter of FIG. 6 undergoes the following steps:
1. The optical filter 200 is flipped upside down.
2. The flipped optical filter is positioned over an array of three Blue/UV microLEDs on a CMOS backplane integrated chip 250. The optical filter is arranged so that the pixel areas of the optical filter are aligned with the three LEDs, and the colour-conversion material is positioned between the LEDs and the DBR.
3. The substrate on the optical filter can optionally be removed or thinned or polished, to tune the transmission characteristics of the filter.

The optical filter 200 and the LED chip are aligned so that the three pixel areas on the optical filter are aligned with a first blue LED 120, a second blue LED 130, and a third blue LED 140.

When the LEDs are turned on, all three LEDs 120, 130, 140 emit blue light. The blue light of the third LED 140 is transmitted through the second region 90 of the optical filter 200, and passes out of the LED device through the transparent substrate 110.

The blue light emitted by the first LED 120 is incident on the green colour-conversion quantum dots 70, so that the quantum dots are excited and emit green light. The DBR reflects any blue light which is not absorbed by the quantum dots, and prevents the blue light from passing through the first region 20 of the optical filter. The DBR does not reflect green light, so the colour-converted green light is transmitted out of the optical filter 200 through the DBR and through the substrate, so that the first LED 120 appears to a viewer to be a green LED, or a green pixel. Similarly, the blue light emitted by the second LED 130 is incident on the red colour-conversion quantum dots 80, so that the quantum dots are excited and emit red light. The DBR reflects any blue light which is not absorbed by the quantum dots, and prevents the blue light from passing through the first region 90 of the optical filter. The DBR does not reflect red light, so the colour-converted red light is transmitted out of the optical filter 10 through the DBR and through the substrate 40, so that the second LED 130 appears to a viewer to be a red LED, or a red pixel.

The optical filter 10 therefore converts an array of blue LEDs into effectively a set of red, green and blue pixels.

In this embodiment, the optical filter is on another substrate which is equivalent to the glass that is current technology for QD colour conversion. A particular advantage of using a porous III-nitride optical filter is the design flexibility and process integration, all within III-nitride material such as GaN. The subsequent integration and/or bonding with microLED pixels is also advantageously much easier, as this involves semiconductor to semiconductor bonding, as opposed to semiconductor to dielectric/glass.

FIG. 7B shows a version of FIG. 7A with electrical n and p contacts. Although the Blue or UV MicroLED pixels are schematically illustrated as a block, the skilled person will appreciate that individual pixels will be formed and electrically isolated from one another in order to be individually operable, as is conventional in the art of LED arrays.

Instead of being formed by first forming the optical filter and the LED chip separately, and then flipping and bonding the filter to the LED chip, the Blue/UV LEDs may alternatively be formed epitaxially over the optical filter (or vice versa). The whole integrated structure may then be bonded to the CMOS backplane as shown in FIG. 7B.

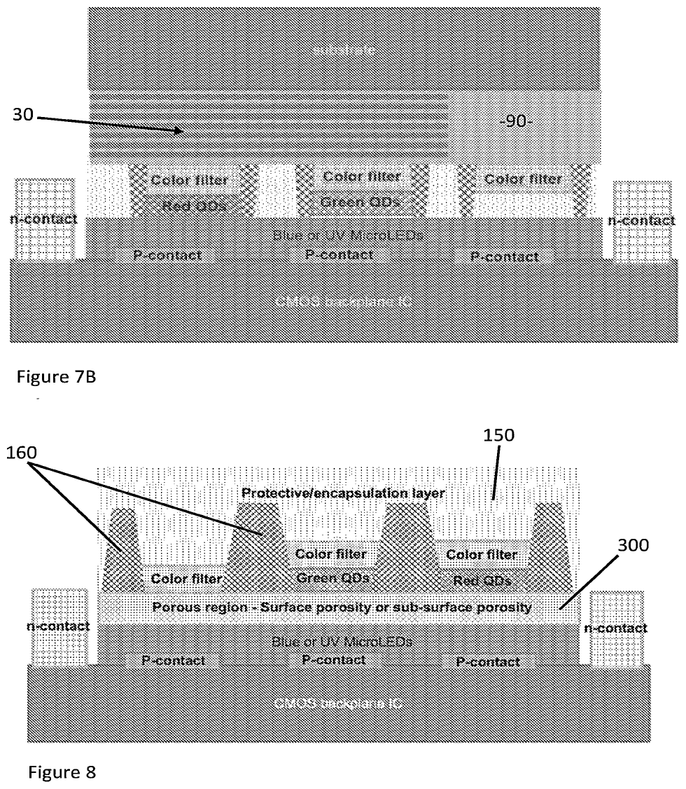

FIG. 8 shows a schematic side-on cross-section of an LED device comprising an optical filter according to an aspect of the present invention.

The device of FIG. 8 may be formed by the following steps:
1. An array of Blue/UV MicroLEDs are epitaxially grown using conventional LED processing steps, and are bonded to a CMOS backplane IC wafer with the required electrical contacts.
2. The original substrate of the LED epi (which is originally on the opposite face of the LEDs from the CMOS backplane) is removed.
3. A Porous region 300 is formed over the Blue/UV MicroLEDs. The porous region may preferably be porous III-nitride material, which may be formed by depositing n-doped III-nitride material followed by an EC etching step. The porous region may comprise a porous surface layer, or one or more sub-surface porous regions. The porous region may be a single porous layer or a plurality of layers having alternating porosities.
4. Deposit the Black Matrix 160, which is typically black epoxy or Photo imageable dielectric. Pattern the black matrix to expose three pixel areas of the MicroLEDs. Adjacent pixel areas are separated by portions of black matrix, in order to avoid cross-talk between different pixels in operation.
5. Green and Red QDs, or other colour-converting materials, are deposited in two of the three pixel areas. No colour-conversion material is deposited in the third pixel area which will act as the blue pixel. The colour-conversion material may be coated on or impregnated into a surface of the porous region.
6. A colour filter material may optionally be deposited in all pixel areas, over the colour-conversion material where it is present.
7. A porous/non-porous layered DBR (not shown in FIG. 8) may optionally then be formed over the two pixel areas comprising the colour-conversion material, while non-DBR semiconductor material may be formed over the blue pixel. As described above, the DBR may be formed by depositing alternating layers of III-nitride material having different doping concentrations, and then electrochemically porosifying every second layer.
8. A protective or encapsulation layer 150 is deposited over the top of the optical filter, to protect the components of the filter from damage.

In this embodiment, the optical filter is incorporated within the LED epi, hence the microLEDs can be processed the normal way and bonded with the CMOS driver. But the optical filter can either be processed initially before the LED epi, or processed again after the microLED processing, so that it forms an optical filter integrated with the LED semiconductor structure.

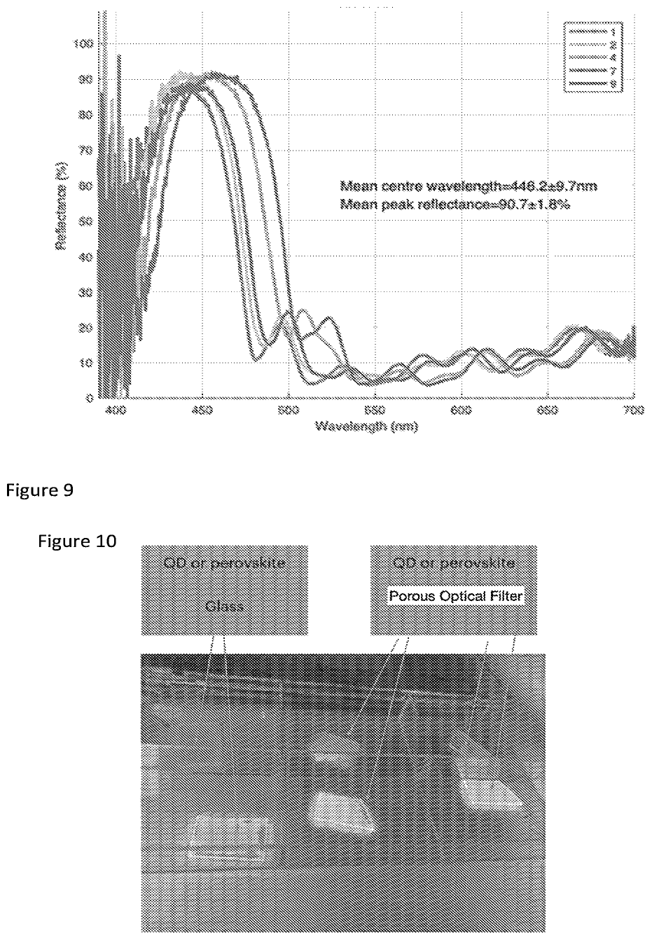

FIG. 9 is a graph of optical reflectance (in %) vs wavelength (nm) measured for five optical filters embodying the present invention. The Figure shows that the five example optical filters exhibit very high reflectance of around 90% between 400-500 nm, which allows blue to reflect, and low reflectance from 500 nm-700 nm, which would allow green and red light to be transmitted through the optical filter and out of the LED device.

FIG. 10 is a photograph illustrating a comparison of the performance of colour-converting materials on glass, and the same colour-converting materials provided on a porous/non-porous DBR as used in preferred embodiments of the present invention. The photographs show that when the same colour-conversion green and red quantum dots are provided on glass and on an optical filter containing a porous/non-porous DBR and both are illuminated with UV light, the colour-conversion material on the optical filter emits much brighter converted green/red light.

As described above, the colour converting material can be any nanoparticles, such as QDs (cadmium or cadmium free)—organic or inorganic, or perovskites (organic or inorganic)

Colour converting materials can be deposited/synthetized, by spin-coating/immersion/dipping/inject printing.

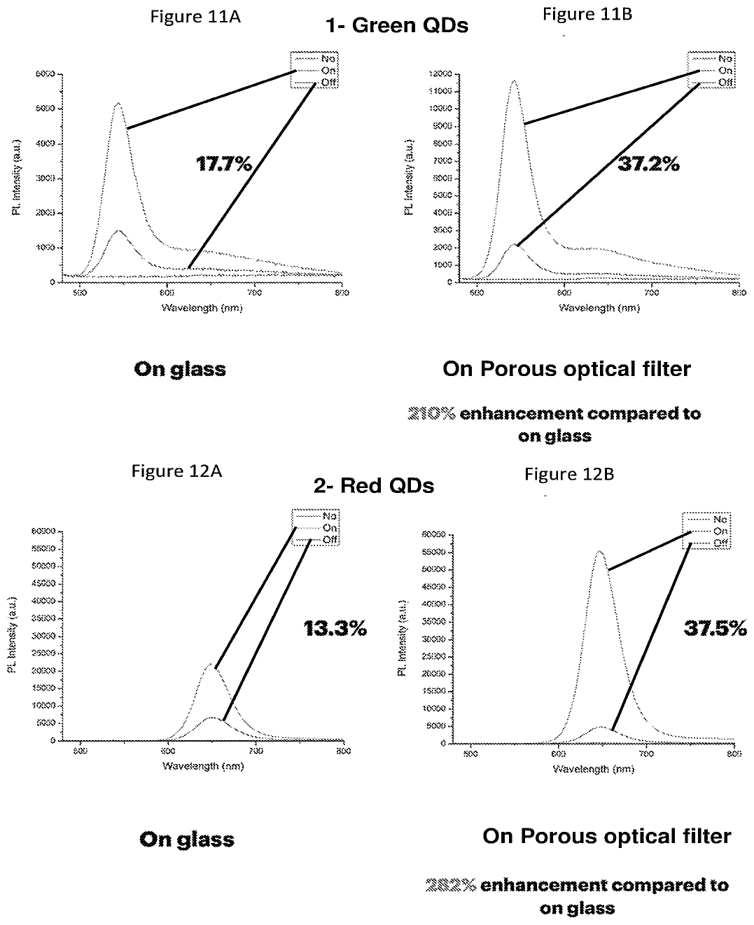

FIG. 11A is a graph of photoluminescence (PL) intensity vs wavelength for green QDs on glass, and FIG. 11B is a graph of photoluminescence (PL) intensity vs wavelength for green QDs on a porous optical filter of the present invention, when both are excited by a 450 nm excitation laser.

As shown in FIGS. 11A and 11B, green colour-conversion quantum dots exhibited a PLQE (photoluminescence quantum efficiency) of 17.7% when excited by a 450 nm excitation laser. However, when the same green colour-conversion quantum dots were provided on the porous layer of an optical filter comprising a porous/non-porous DBR, the PLQE rose to 37.2%. The optical filter of the present invention therefore provided a 210% enhancement of the blue-to-green colour-conversion PLQE compared to the same material on glass.

FIG. 12A is a graph of photoluminescence (PL) intensity vs wavelength for red QDs on glass, and FIG. 12B is a graph of photoluminescence (PL) intensity vs wavelength for red QDs on a porous optical filter of the present invention, when both are excited by a 450 nm excitation laser.

As shown in FIGS. 12A and 12B, red colour-conversion quantum dots exhibited a PLQE (photoluminescence quantum efficiency) of 13.3% when excited by a 450 nm excitation laser. However, when the same green colour-conversion quantum dots were provided on the porous layer of an optical filter comprising a porous/non-porous DBR, the PLQE rose to 37.5%. The optical filter of the present invention therefore provided a 282% enhancement of the blue-to-red colour-conversion PLQE compared to the same material on glass.

1. An LED device, comprising:
a plurality of light-emitting diodes (LEDs), and
an optical filter arranged to filter light emitted by the plurality of LEDs,
in which the optical filter comprises a first region arranged to filter light emitted from a first portion of the plurality of LEDs, in which the first region of the optical filter comprises a Distributed Bragg Reflector (DBR) configured to prevent transmission of light of a predetermined wavelength λ₁.

2. An LED device according to claim 1, in which the plurality of LEDs are monochromatic LEDs, preferably monochromatic blue LEDs or UV LEDs.

3. An LED device according to claim 1, in which the optical filter comprises a second region arranged to allow transmission of light emitted from a second portion of the plurality of LEDs

4. An LED device according to claim 1, in which λ₁ is the emission wavelength of the plurality of LEDs, so that second portion of the optical filter is configured to allow transmission of light with wavelength λ₁ emitted by the second portion of the plurality of LEDs, and/or the first portion of the optical filter is configured to prevent transmission of light of wavelength λ₁ emitted by the first portion of the plurality of LEDs.

5. An LED device according to claim 3, in which the second portion of the plurality of LEDs are monochromatic blue LEDs, and the second region of the optical filter is configured to transmit blue light emitted by the blue LEDs.

6. An LED device according to claim 1, in which the DBR is configured to prevent transmission of blue light.

7. An LED device according to claim 1, in which the first region of the optical filter is configured to transmit green and/or red light.

8. An LED device according to claim 1, in which the first portion of the plurality of LEDs comprises LEDs configured to emit green light, and/or LEDs configured to emit red light.

9. An LED device according to claim 1, comprising a colour-conversion material positioned between the first portion of the LEDs and the DBR, the colour-conversion material being configured to emit light at one or more wavelengths different from the emission wavelength λ₁ of the first portion of LEDs.

10. An LED device according to claim 9, in which the colour-conversion material is a plurality of colour-conversion quantum dots.

11. An LED device according to claim 9, in which the colour-conversion material comprises a perovskite material, preferably a plurality of colour-conversion perovskite nanocrystals.

12. An LED device according to claim 9, in which the colour-conversion material is positioned over discrete subsets of the LEDs in the first portion of the plurality of LEDs.

13. An LED device according to claim 1, in which the first region of the optical filter comprises a porous layer positioned between the LEDs and the DBR, preferably a porous layer of III-nitride material.

14. An LED device according to claim 13, in which the porous layer is coated or impregnated with colour-conversion material, preferably with colour-conversion quantum dots or colour-conversion perovskite material.

15. An LED device according to claim 14, in which different colours of colour-conversion material are coated or impregnated into the porous layer of the optical filter in discrete regions, so that a first colour of colour-conversion material is positioned above a subset of the first portion of the plurality of LEDs, and/or a second colour of colour-conversion material is positioned above another subset of the first portion of the plurality of LEDs.

16. An LED device according to claim 14, in which green colour-conversion material is positioned above a subset of the first portion of the plurality of LEDs, and/or red colour-conversion material is positioned above another subset of the portion of the plurality of LEDs, or vice versa.

17. An LED device according to claim 14, in which the porous layer of the optical filter comprises a plurality of mesas forming the discrete regions, such that a first set of mesas are impregnated with green colour-conversion material, and/or a second set of mesas are impregnated with red colour-conversion material is.

18. An LED device according to claim 14, in which quantum dots or perovskite nanocrystals are embedded in the porous layer of the optical filter at a depth of between 1 nm to 200 nm.

19. An LED device according to claim 9, comprising a colour filter material positioned between the colour-conversion material and the DBR.

20. An LED device according to claim 1, in which the DBR comprises a stack of layers of III-nitride semiconductor material, in which alternating layers in the stack have different porosities, and therefore different refractive indices.

21. An LED device according to claim 20, in which the layers in the stack have a thickness equal to λ₁/4, where λ₁ is the wavelength of light the DBR is configured to filter out.

22. An LED device according to claim 1, in which the optical filter comprises an optically transparent substrate layer attached to the DBR, preferably in which the substrate layer is sapphire or glass.

23. An LED device according to claim 1, comprising:
a first blue/UV LED positioned beneath the second region of the optical filter, in which the second region of the optical filter is configured to allow transmission of blue/UV light out of the device;
a second blue/UV LED positioned beneath the DBR in the first region of the optical filter, and green colour-conversion material positioned between the second blue/UV LED and the DBR, in which the DBR is configured to prevent the transmission of blue/UV light but to allow the transmission of green light out of the device; and
a third blue/UV LED positioned beneath the DBR in the first region of the optical filter, and red colour-conversion material positioned between the third blue/UV LED and the DBR, in which the DBR is configured to prevent the transmission of blue/UV light but to allow the transmission of red light out of the device.

24. An LED device according to claim 1, in which the plurality of LEDs form part of a CMOS blue LED wafer.

25. An optical filter for an LED device comprising a plurality of light-emitting diodes (LEDs), the optical filter comprising:
a first region arranged to filter light emitted from a first portion of the plurality of LEDs, in which the first region of the optical filter comprises a Distributed Bragg Reflector (DBR) configured to prevent transmission of light of a predetermined wavelength λ₁.

26. An optical filter according to claim 25, comprising:
a second region arranged to transmit light emitted from a second portion of the plurality of LEDs.

27. An optical filter according to claim 25, in which λ₁ is the emission wavelength of the plurality of LEDs, so that the second region of the optical filter is configured to allow transmission of light with wavelength λ₁ emitted by the second portion of the plurality of LEDs, and/or the first portion of the optical filter is configured to prevent transmission of light of wavelength λ₁ emitted by the first portion of the plurality of LEDs.

28. An optical filter according to claim 25, in which the second region of the optical filter is configured to transmit blue or UV light emitted by a plurality of blue or UV LEDs.

29. An optical filter according to claim 25, in which the DBR is configured to prevent transmission of blue/UV light.

30. An optical filter according to claim 25, in which the optical filter comprises a colour-conversion material positioned between the blue LEDs and the DBR, the colour-conversion material being configured to emit light at one or more wavelengths different from that of the blue LEDs.

31. An optical filter according to claim 25, in which the first region of the optical filter comprises a porous layer positioned between the LEDs and the DBR, preferably a porous layer of III-nitride material.

32. An optical filter according to claim 31, in which the porous layer is coated or impregnated with colour-conversion material, preferably colour-conversion quantum dots or colour-conversion perovskite nanocrystals.

33. An optical filter according to claim 31, in which different colours of colour-conversion material are coated or impregnated into the porous layer of the optical filter in discrete regions, so that colour-conversion material of a first colour is positioned above a subset of the first portion of the plurality of LEDs, and/or colour-conversion material of a second colour is positioned above another subset of the first portion of the plurality of LEDs.

34. An optical filter according to claim 33, in which green colour-conversion material is positioned above a subset of the first portion of the plurality of LEDs, and/or red colour-conversion material is positioned above another subset of the portion of the plurality of LEDs, or vice versa.

35. An optical filter according to claim 31, in which the porous layer of the optical filter comprises a plurality of mesas forming the discrete regions, such that a first set of mesas are impregnated with green colour-conversion material, and/or a second set of mesas are impregnated with red colour-conversion material.

36. An optical filter according to claim 30, comprising a colour filter material positioned between the colour-conversion material and the DBR.

37. An optical filter according to claim 25, comprising an encapsulation layer forming a surface layer of the optical filter.

38. An optical filter according to claim 25, in which the optical filter comprises an optically transparent substrate layer attached to the DBR, preferably in which the substrate layer is sapphire or glass.

39. Use of an optical filter according to claim 25 to convert a plurality of monochromatic LEDs into an LED device for emitting light of a plurality of different colours.
